(19) United States
(12) Patent Application Publication
(10) Pub. No.: US 2015/0263082 A1
(43) Pub. Date: Sep. 17, 2015

(54) INDUCTOR STRUCTURES WITH IMPROVED QUALITY FACTOR

(71) Applicant: AItera Corporation, San Jose, CA (US)

(72) Inventors: Chun Lee Ler, Tangkak (MY); Shuxian Chen, San Jose, CA (US)

(73) Assignee: AItera Corporation, San Jose, CA (US)

(21) Appl. No.: 14/204,617

(22) Filed: Mar. 11, 2014

(51) Int. Cl. H01L 49/02

(52) U.S. Cl. CPC H01L 28/10

(57) ABSTRACT

In one embodiment, an inductor structure is provided. The inductor structure includes a first elongated segment and a second elongated segment. The first elongated segment runs parallel to a longitudinal axis of the inductor structure. The second elongated segment also runs parallel to the longitudinal axis. The first elongated segment conveys a current in a first direction and the second elongated segment conveys the current in a second direction that is different than the first direction.

### BACKGROUND

Transceiver circuits are generally designed to transmit and receive high speed signals. To enable high speed transmissions, transceiver circuitry may include a high frequency and low noise voltage-controlled oscillator (VCO) circuit. Although the VCO circuit design is capable of supporting high speed transmissions, it is generally limited to 10 Gigahertz (GHz). One of the reasons for such limitation is because the ring oscillator (RO) circuit, which is a circuit in the VCO circuit, has a poor phase noise performance.

Another type of VCO circuit design is the inductor-capacitor VCO (LC-VCO) circuit. The LC-VCO circuit enables data transmissions at speeds greater than 10 GHz. Furthermore, it generally has low phase noise characteristics. However, the LC tank in the LC-VCO circuit generally includes a low quality factor (i.e., Q factor) inductor. For example, the quality factor for LC tank may be less than 25 at 16 GHz.

An inductor structure may exhibit a low Q factor because of the relatively large eddy current induced on the semiconductor substrate when an electrical current is transmitted through the inductor structure. There are ways to reduce eddy current such as forming a pattern ground shield (PGS) between the substrate and the metal layer where the inductor structure is formed. The PGS structure can help reduce the eddy current formed on the substrate. However, the PGS structure may not be an efficient way to reduce power loss from eddy current. In fact, eddy currents may be generated on the PGS structure instead of the substrate.

### SUMMARY

Embodiments described herein include a high Q factor inductor structure and a method to manufacture the inductor structure. It should be appreciated that the embodiments can be implemented in numerous ways, such as a process, an apparatus, a system, a device, or a method. Several embodiments are described below.

In one embodiment, an inductor structure is provided. The inductor structure includes a first elongated segment and a second elongated segment. The first elongated segment runs parallel to a longitudinal axis of the inductor structure. The second elongated segment also runs parallel to the longitudinal axis. The first elongated segment conveys a current in a first direction and the second elongated segment conveys the current in a second direction that is different than the first direction.

In another embodiment, an integrated circuit is described. The integrated circuit includes a substrate, an interconnect stack and an inductor. The interconnect stack is formed on the substrate. The inductor is formed in the interconnect stack. The inductor includes a first and second elongated member. The first elongated member conveys a current in a first direction. The second elongated member conveys the current in a second direction that is opposite from the first direction.

Alternatively, a method of manufacturing an integrated circuit having a substrate and a dielectric stack on the substrate is described. The method includes forming of a first elongated segment in the dielectric stack. Next, a second elongated segment is formed in the dielectric stack. The first and second elongated segments form a part of an inductor and that the first and second elongated segments convey currents in opposing directions.

Further features of the invention, its nature and various advantages will be more apparent from the accompanying drawings and the following detailed description of the preferred embodiments.

### BRIEF DESCRIPTION OF THE DRAWINGS

FIG. 1 is an illustrative inductive-capacitive voltage-controlled oscillator (LCVCO) circuit in accordance with one embodiment of the present invention.

FIG. 2 shows a cross-sectional view of an integrated circuit that includes an inductor structure formed in one metal layer in accordance with one embodiment of the present invention.

FIG. 3 shows a cross-sectional view of an integrated circuit having an inductor structure formed in two metal layers in accordance with one embodiment of the present invention.

FIG. 4 shows a top view of a rectangular shaped inductor structure in accordance with one embodiment of the present invention.

FIG. 5 shows a top view of a U-shaped inductor structure in accordance with one embodiment of the present invention.

FIG. 6 shows a top view of a two turn U-shaped inductor structure in accordance with one embodiment of the present invention.

FIG. 7 shows a top view of a dual U-shaped inductor structure in accordance with one embodiment of the present invention.

FIG. 8 shows a flowchart of a manufacturing method of an inductor structure in accordance with one embodiment of the present invention.

### DETAILED DESCRIPTION

The following embodiments describe a high Q factor inductor structure and a method to manufacture the inductor structure. It will be obvious, to one skilled in the art, that the present exemplary embodiments may be practiced without some or all of these specific details. In other instances, well-known operations have not been described in detail in order not to unnecessarily obscure the present embodiments.

Throughout this specification, when an element is referred to as being “connected” or “coupled” to another element, it can be directly connected or coupled to the other element or electrically connected or coupled to the other element with yet another element interposed between them.

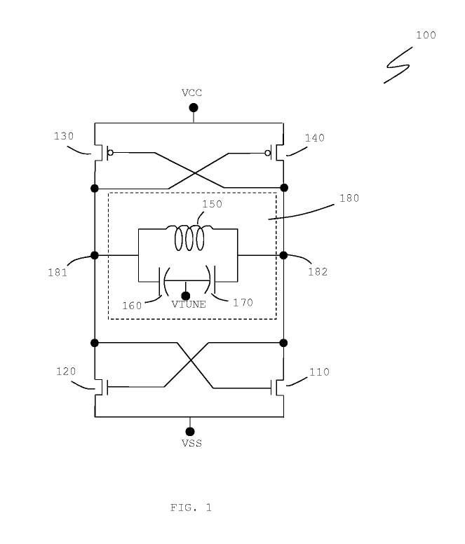

FIG. 1, meant to be illustrative and not limiting, illustrates an inductive-capacitive voltage-controlled oscillator (LCVCO) circuit in accordance with one embodiment of the present invention. LCVCO circuit 100 may include two p-channel metal oxide semiconductor (PMOS) transistors 130 and 140, two n-channel metal oxide semiconductor (NMOS) transistors 110 and 120 and inductive-capacitive (LC) tank 180. LC tank 180 includes capacitors 160 and 170 and inductor 150. In one embodiment, inductor 150 may have a physical inductor structure similar to inductor structure 400, 500, 600 or 700 of respective FIGS. 4-7.

As shown in the embodiment of FIG. 1, one of the source-drain terminals of PMOS transistors 130 and 140 are coupled to a power supply voltage level (e.g., VCC). The other source-drain terminals of PMOS transistors 130 and 140 are coupled to terminals 181 and 182 of LC tank 180. In addition to that, the other source-drain terminals of PMOS transistors 130 and 140 may also be coupled to the corresponding source-drain terminals of NMOS transistors 120 and 110 and the respective gate terminals of NMOS transistors 110 and 120. A source-drain terminal of each of NMOS transistors 110 and 120 is coupled to a ground voltage level (i.e., VSS). Although LCVCO circuit 100 with a specific arrangement is shown in the embodiment of FIG. 1, it should be appreciated that LCVCO circuits with different arrangements may be used in this context.

LCVCO circuit 100 may be utilized to generate a periodic signal at a specific frequency. As an example, LCVCO circuit 100 may generate a periodic signal with a frequency greater than 10 gigahertz (GHz). In one embodiment, the generated signal may be utilized by circuits in transceiver circuitry, for example, a physical media attachment (PMA) circuit, a physical coding sublayer (PCS) circuit, serializer/deserializer (SerDes) circuitry and/or a phase locked loop (PLL) circuit.

It should be appreciated that an integrated circuit that includes LCVCO circuit 100 may be a programmable logic device (PLD), for example, a field programmable gate array (FPGA) device. Alternatively, the integrated circuit may be an application specific integrated circuit (ASIC) device or application specific standard products (ASSP) device, such as, a memory device or a microprocessor device.

LCVCO circuit 100 may also be tuned to generate periodic signals at different operating frequencies. As shown in the embodiment of FIG. 1, the tuning voltage (VTUNE) that is provided to capacitors 160 and 170 may shift the resonant frequency of LC tank 180. Consequently, the change to LC tank 180 resonating frequency may alter the frequency of the generated signal. For example, when VTUNE voltage is increased, a signal with a relatively high frequency is generated. Alternatively, when VTUNE voltage is decreased, a signal with a relatively low frequency is generated.

Additionally, LCVCO circuit 100 may also have a low phase noise characteristic. The low phase noise characteristic may help to generate a low jitter high frequency periodic signal, which may increase the sensitivity of the transceiver circuitry to detect an incoming high speed data.

Furthermore, LC tank 180 formed in LCVCO circuit 100 has a high Q factor. It should be appreciated that a Q factor is a dimensionless parameter that describes under-damp characteristics of LC tank 180. For example, a high Q factor suggests the amount energy that is lost from the LC tank 180 is lower than the amount of energy that is stored in LC tank 180. In one embodiment, inductor 150 within LC tank 180 may have a Q factor that is greater than 8.

FIG. 2, meant to be illustrative and not limiting, illustrates a cross-sectional view of an integrated circuit that includes an inductor structure formed in one metal layer in accordance with one embodiment of the present invention. Integrated circuit 200 includes semiconductor substrate 210, dielectric layers 230, 240 and 250, and metal layers 245 and 255. In one embodiment, integrated circuit 200 may include LCVCO circuit 100 of FIG. 1. It should be appreciated that an actual cross section of an integrated circuit may be more complicated (e.g., more layers, structures, etc.) than the cross-sectional view of integrated circuit 200 and specific elements may not be shown in order to not unnecessarily obscure the present invention. For example, an actual integrated circuit may include seven metal layers, whereas only two metal layers 245 and 255 are shown in integrated circuit 200.

It should be noted that the cross section shown in the embodiment of FIG. 2 shows the configuration of inductor structure 227 in integrated circuit 200 and the manner in which the inductor structure may be coupled to transistors 220 and 225. Within the embodiment of FIG. 2, transistors 220 and 225 are formed on semiconductor substrate 210. Transistors 220 and 225 may be similar to PMOS transistors 130 and 140 (or NMOS transistors 110 and 120) of FIG. 1, in one embodiment.

As shown in the embodiment of FIG. 2, inductor structure 227 is formed in metal layer 255. Inductor structure 227 includes two segments, i.e., segments 231 and 232. Segment 231 is coupled to a corresponding source-drain region of transistor 225 by way of respective through-hole vias 235 and 247 and signal path 246 on metal layer 245. Similarly, segment 232 is coupled to a corresponding source-drain region of transistor 220 by way of respective through-hole vias 236 and 249 and signal path 248 on metal layer 245. The through-hole vias 235 and 236 extends through dielectric layer 230 and through-hole via 247 and 249 extends through dielectric layer 240. In one embodiment, through-hole vias 235, 236, 247 and 249 may be plated through hole (PTH) vias.

Integrated circuit 200 may further include a metal shielding (not shown) just above inductor structure 227. The metal shielding may shield inductor structure 227 from crosstalk. In one embodiment, the metal shielding may shield crosstalk generated by transistors 220 and 225 from segments 232 and 231, respectively, of inductor structure 227.

Segments 231 and 232 transmit an electrical in opposite directions. In one embodiment, transmitting electrical current in opposite directions between the respective segments 231 and 232 may reduce the total amount of induced eddy current on the surface of semiconductor substrate 210. Therefore, inductor structure 227 may have a high Q factor and relatively low phase noise. In one exemplary embodiment, inductor structure 227 may have a Q factor of 11 and a phase noise improvement of approximately 0.4 decibels relative to carrier (dBc). Furthermore, the Q factor may also be relatively high (e.g., Q factor of 8) at significantly high frequencies (e.g., frequency of 50 GHz).

It should be appreciated that eddy current is generated when magnetic fields (from the electrical current transmitting through segments 231 and 232 of inductor structure 227) induce electric current on semiconductor substrate 210. The amount of induced eddy current may depend on three factors: (i) the resistivity of semiconductor substrate 210, (ii) the distance between segments 231 and 232, and (iii) the distance between inductor 227 and semiconductor substrate 210.

For example, a low resistivity semiconductor substrate 210 (e.g., substrate resistivity lower than 10 Ohms per cm) may induce a high amount of eddy current. In contrast, a high resistivity semiconductor substrate 210 may induce a lower amount of eddy current. However, semiconductor substrate 210 with a low resistivity may be preferred for optimized transistor performance. Low resistivity semiconductor substrate 210 may be utilized to form a transistor ground plane that makes latch-up less likely. In the embodiment of FIG. 2, semiconductor substrate 210 may have a resistivity of less than 10 Ohm/cm.

Additionally, segments 231 and 232 transmitting electrical current in opposite directions may not induce as much eddy current when the distance between segments 231 and 232 is relatively small. The reduction in eddy current may be due to the fact that the magnetic fields generated by segments 231 and 232 may partially cancel out each other. A person skilled in the art appreciates the right-hand rule (or corkscrew-rule) with respect to the electric current and the magnetic field. In one embodiment, the distance to achieve the eddy current cancellation effect is less than 15 microns (μm).

It should be appreciated that the Q factor value inversely related to the amount of induced eddy current on the surface of semiconductor substrate 210. When a large amount of eddy current is induced, a large amount of energy may be lost that leading to a low Q factor value. In contrast, when a small amount of eddy current is induced, a small amount of energy may be lost that leads to a high Q factor value. The embodiment of FIG. 2 may have a high Q factor value because the magnetic fields generated by segments 231 and 232 may partially cancel out each other inducing a small amount of eddy current on semiconductor substrate 210.

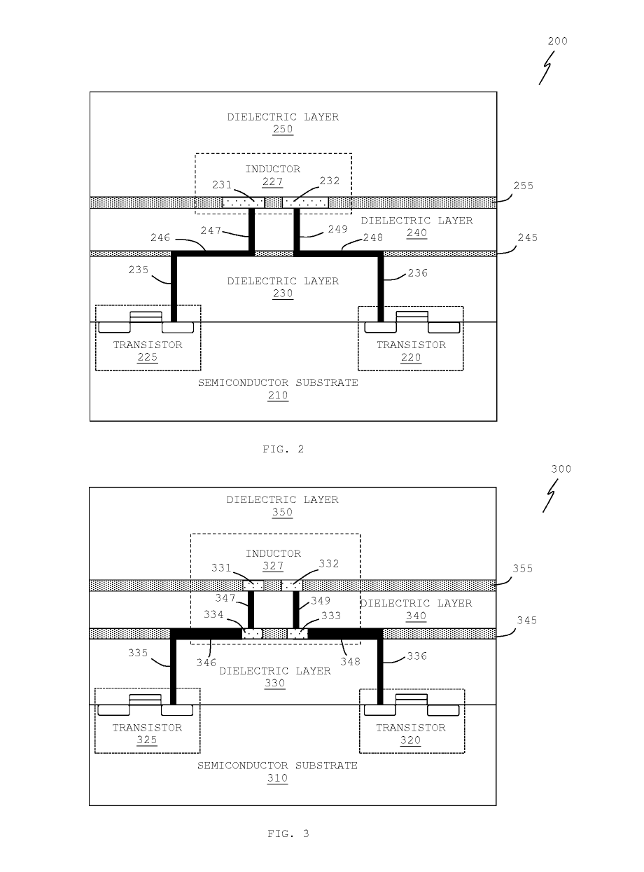

FIG. 3, meant to be illustrative and not limiting, illustrates a cross-sectional view of another integrated circuit having an inductor structure formed in two metal layers in accordance with one embodiment of the present invention. Integrated circuit 300 includes semiconductor substrate 310, dielectric layers 330, 340 and 350, and metal layers 345 and 355. In one embodiment, semiconductor substrate 310, dielectric layers 330, 340 and 350, and metal layers 345 and 355 may be similar to semiconductor substrate 210, dielectric layers 230, 240 and 250 and metal layers 245 and 255, respectively, and for the sake of brevity, will not be repeated here.

As shown in the embodiment of FIG. 3, inductor structure 327 is formed in metal layers 345 and 355. Inductor structure 327 may be a serial-stacked inductor structure 327 with segments 334, 331, 332 and 333 are coupled in series. Therefore, a relatively small space is required on each of the metal layers 345 and 355 compared to when inductor structure 327 is formed fully on one metal layer (e.g., either on metal layer 345 or 355). Alternatively, inductor structure 327 may be a parallel-stacked inductor structure 327, with segments 334 and 331 being parallel to segments 333 and 332. Segments 331 and 332, which are formed on metal layer 355, transmit electrical current in opposite directions relative to each other. Similarly, segments 333 and 334, which are formed on metal layer 345, transmit electrical current in opposite directions relative to each other.

FIG. 4, meant to be illustrative and not limiting, illustrates a top view of a rectangular shaped inductor structure in accordance with one embodiment of the present invention. Inductor structure 400 includes five major segments, i.e., segments 411-415. In one embodiment, inductor structure 400 may be inductor 150 of FIG. 1 or inductor 227 of FIG. 2.

A signal may be received by inductor structure 400 through terminal IN1 and is transmitted out from inductor structure 400 through terminal OUT1. The electrical current I1 propagates according to the direction shown by the arrows in FIG. 4.

Referring still to FIG. 4, segments 411, 412 and 414 forms a major part of inductor structure 400. Furthermore, segment 414 is formed parallel to segments 411 and 412. In one embodiment, the distance(X) between segment 414 and segments 411 and 412 may be less than 15 μm. Electrical current I1 travels through segment 414 in a direction that is opposite to that of the electrical current travelling through segments 411 and 412. The close proximity of segment 414 and segments 411 and 412 and the current travelling in opposite directions through segments 414, 411 and 412 may reduce eddy current on the semiconductor substrate (e.g., semiconductor substrate 210 of FIG. 2 or semiconductor substrate 310 of FIG. 3), and may provide a high Q factor across a large bandwidth.

In one exemplary embodiment, inductor structure 400 that has an inductance valued at a 0.2 nanohenry (nH) may have segments 413 and 415 at a length of 24 μm and segments 414 and segments 411 and 412 (taken together) at a length of 300 μm. In total, inductor structure 400 may encompass an area of 7200 μm². Inductor structure 400 may also have a maximum Q factor of 11.6 at 25 Ghz.

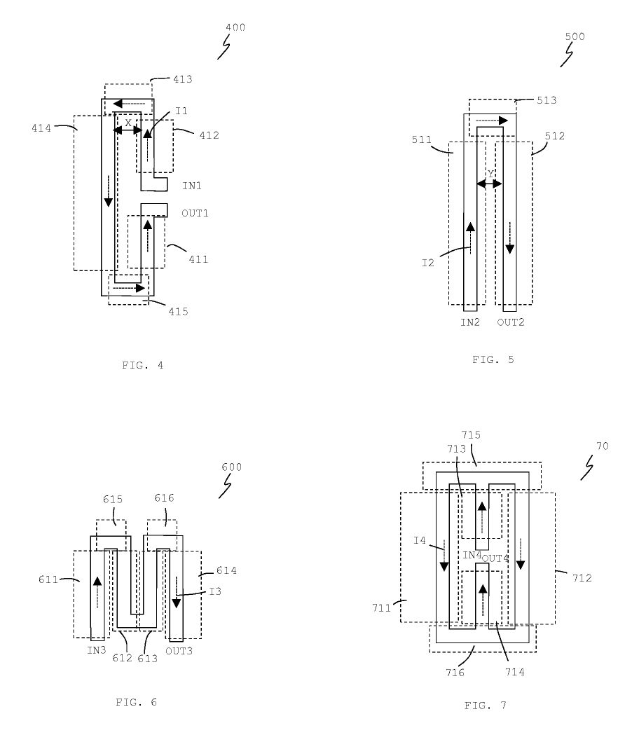

FIG. 5, meant to be illustrative and not limiting, illustrates a top view of a U-shaped inductor structure in accordance with one embodiment of the present invention. Inductor structure 500 includes three segments, i.e., segments 511-513. Inductor structure 500, similar to inductor structure 400 of FIG. 4, may be implemented as the physical structure for inductor 150 of FIG. 1 or inductor structure 227 of FIG. 2.

Signals may be transmitted into inductor structure 500 through terminal IN2 and transmitted out through terminal OUT2.

Segments 511 and 512 form a large part of inductor structure 500. Segment 511 is parallel to segment 512. The distance (Y) between the two segments, i.e., segments 511 and 512, may be less than 15 μm. Electrical current I2 travels in opposite directions through the respective segments 511 and 512. Therefore, similar to inductor structure 400 of FIG. 4, a small amount of eddy current is formed on the semiconductor substrate (e.g., semiconductor substrate 210 of FIG. 2 or semiconductor substrate 310 of FIG. 3), and a high Q factor across a large bandwidth may be observed.

For inductor structure 500 that has an inductance valued at 0.2 nH, segments 511 and 512 may have a length of 285 μm and segment 513 may have a length of 26 μm. Therefore, inductor structure 500 may encompass an area of 7410 μm², (which is larger than 0.2 nH inductor structure 400 of FIG. 4). Inductor structure 500 may have a maximum Q factor of 12.2 at 25 Ghz.

It should be appreciated that inductor structure 500 may be preferred over inductor structure 400 of FIG. 4 when a high Q factor is needed and there is no constraint on space in the metal layers. Alternatively, inductor structure 400 of FIG. 4 may be preferred when a high Q factor is needed and there is a space constraint in the metal layers.

FIG. 6, meant to be illustrative and not limiting, illustrates a top view of a two-turn U-shaped inductor structure in accordance with one embodiment of the present invention. Inductor structure 600 includes six segments, i.e., segments 611-616. As shown in the embodiment of FIG. 6, inductor structure 600 may be similar to two half-sized inductor structures 500 of FIG. 5 coupled in series. However, it should be appreciated that the two-turn U-shaped inductor structure may come in different arrangement than being two half-sized inductor structures 500 of FIG. 5. The arrangement of segments 611-616 to form a two-turn U-shaped inductor structure is as depicted in FIG. 6. Segments 611, 615 and 612 form the first U-shaped inductor structure, and segments 613, 616 and 614 forms a second U-shaped structure. Inductor structure 600, may be implemented on a single metal layer (e.g., inductor 227 of FIG. 2) or in two different metal layers (e.g., inductor 337 of FIG. 3).

Electrical current I3 is transmitted into inductor structure 600 through terminal IN3 and is transmitted out of inductor structure 600 through terminal OUT3. As shown in the embodiment of FIG. 6, segments 611-614 are parallel to each other. The distance between two adjacent segments, i.e., segments 611 and 612, segments 612 and 613 or segments 613 and 614, may be less than 15 μm. The electrical current travels through two adjacent segments in opposite directions. Therefore, inductor structure 600 may generate a low eddy current and a high Q factor across a large bandwidth.

For inductor structure 600 formed to have an inductance that is valued at 0.2 nH, segments 611-614 may have a length of 142 μm and segments 615 and 616 may have a length of 26 μm, respectively. Therefore, inductor structure 600 may encompass an area of 7384 μm2, (which is relatively similar in size to 0.2 nH inductor structure 500 of FIG. 5). Similarly, inductor structure 600 may have a Q factor of 12.2 at 25 Ghz. In some instances, inductor structure 600 may be preferred over inductor structure 500 of FIG. 5 because inductor structure 600 may be formed in two different metal layers similar to inductor structure 327 of FIG. 3. Therefore, if there is a space constraint in each metal layer, but there are multiple metal layers within an integrated circuit, then inductor structure 600 may be preferred.

It should be appreciated that there may be more than two-turn U-shaped inductor structure unlike two-turn U-shaped inductor structure 600 as shown in FIG. 6. Such structure may be termed as multi-turn U-shaped inductor structures. For example, a three-turn U-shaped inductor structure that has three turns instead of the two turns as shown in the embodiment of FIG. 6.

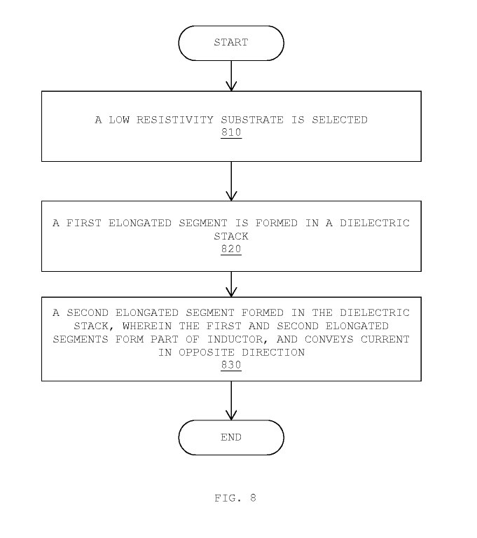

FIG. 7, meant to be illustrative and not limiting, illustrates a top view of a dual U-shaped inductor structure in accordance with one embodiment of the present invention. Inductor structure 700 includes six segments, i.e., segments 711-716. Inductor structure 700 may be similar to two inductor structures 600 of FIG. 6 located opposite to each other and being coupled at their fingers end. Inductor structure 700, similar to inductor structure 600 of FIG. 6, may be implemented on a single metal layer (e.g., inductor structure 227 of FIG. 2) or in two different metal layers (e.g., inductor structure 327 of FIG. 3). However, it should be appreciated that other implementation of dual U-shaped inductor structure may be varied form from inductor structure 700, for example, the dual U-shaped inductor structure may be implemented on two layers (e.g., inductor structure 300 of FIG. 3).

Electrical current I4 may be transmitted into inductor structure 700 through terminal IN4 and may be transmitted out through terminal OUT4. In the embodiment of FIG. 7, segments 711-714 are parallel to each other, while segments 715 and 716 are parallel to each other. The distance between two adjacent segments, i.e., segment 711 and segment 713 or 714, segment 712 and segment 713 or 714 may be less than 15 μm. Electrical current I4 in any two adjacent segments travels in opposite directions.

Therefore, inductor structure 700 may induce a low eddy current and a high Q factor across a large bandwidth.

For inductor structure 700 formed for an inductance that is valued at 0.2 nH, segments 711 and 712 or collectively segment 713 and 714 may have a length of 371 μm and segments 715 and 716 may have a length of 56 μm, respectively. Therefore, inductor structure 700 may encompass an area of 20776 μm², (which is significantly larger compared to 0.2 nH inductor structure 400, 500 or 600 of respective FIGS. 4-6). Similarly, inductor structure 700 may have a maximum Q factor of 14.2 at 25 Ghz. Inductor structure 700 may be preferred over the abovementioned inductor structures 400, 500 and 600 of respective FIGS. 4-6 because inductor structure 700 may provide a higher Q factor compared to all the other structures.

It should be appreciated that inductor structures 400, 500, 600 or 700 of respective FIGS. 4-7 are similar to a “rectangular shaped” inductor structure. This is because the angle between two connecting segments is a right angle (i.e., 90 degrees). For example, in inductor structure 400, segments 412 and 413, segments 413 and 414, segments 414 and 415 and segments 415 and 411 each have right angles between them. However, it should be appreciated that the inductor structure may form other shapes, for example, a pentagonal shape, a hexagonal shape, and an octagonal shape.

Inductor structures 400, 500, 600 or 700 of respective FIGS. 4-7 may be utilized in a LCVCO circuit (e.g., LCVCO circuit 100 of FIG. 1). In addition to that, the inductor structures 400, 500, 600 and 700 of respective FIGS. 4-7 may also be utilized in a high-Q filter circuit, a low-noise amplifier circuit, or a frequency divider circuit.

FIG. 8, meant to be illustrative and not limiting, is a flowchart of a method of manufacturing an inductor structure in accordance with one embodiment of the present invention. The inductor structure may have a top view similar to inductor structure 400, 500, 600 or 700 of respective FIGS. 4-7. At step 810, a low resistivity substrate is selected. The low resistivity substrate may be similar to semiconductor substrate 210 of FIG. 2 or semiconductor substrate 310 of FIG. 3. In one embodiment, the low resistivity substrate may have a resistivity of less than 10 Ohm/cm. At step 820, a first elongated segment is formed in a dielectric stack. The dielectric stack is formed above the low resistivity substrate. The dielectric stack includes a plurality of metal layers (e.g., metal layers 245 and 255 of FIG. 2) and a plurality of dielectric layers (e.g., dielectric layers 230, 240 and 250). The first elongated segment may be inductor segment 231 of FIG. 2. Alternatively, when manufacturing an inductor structure that is similar to inductor structure 500 of FIG. 5, the first elongated segment may be segment 511 of FIG. 5.

At step 830, a second elongated segment is formed in the dielectric stack. The second elongated segment also forms a part of the inductor structure. The second elongated segment is in close proximity to the first elongated segment (e.g., at a distance less than 15 μm). The second elongated segment may transfer electrical current in an opposite direction compared to the first elongated segment. In one embodiment, the second elongated segment may be inductor segment 232 of FIG. 2. Alternatively, when manufacturing an inductor structure similar to inductor structure 500 of FIG. 5, the second elongated segment may be segment 512 of FIG. 5. The electrical current that is transmitted in the first and second elongated segments may induce a low eddy current on the low resistive semiconductor substrate. Therefore, the Q factor that is generated from the inductor structure that is manufactured using this method is high, for example, the Q factor may be greater than 8. It should be appreciated that steps 820 and 830 may be performed at the same time (i.e., at the same processing step) when fabricating the inductor structure that is formed on one metal layer.

The method may also include other steps, for example, forming of additional segments to manufacture an inductor structure similar to inductor structure 400, 500, 600 or 700 of respective FIGS. 4-7. Furthermore, the method may also include forming of additional elongated segments on different metal layers (e.g., inductor segment 331 and 332 of FIG. 3).

The embodiments thus far have been described with respect to integrated circuits. The structures and techniques described herein may be incorporated into other suitable circuits, in addition to the ones described above. For example, they may be incorporated into numerous types of devices such as programmable logic devices, application specific standard products (ASSPs), and application specific integrated circuits (ASICs). Examples of programmable logic devices include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The programmable logic device described in one or more embodiments herein may be part of a data processing system that includes one or more of the following components: a processor; memory; IO circuitry; and peripheral devices. The data processing can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by ALTERA Corporation.

Although the methods of operations were described in a specific order, it should be understood that other operations may be performed in between described operations, described operations may be adjusted so that they occur at slightly different times or described operations may be distributed in a system which allows occurrence of the processing operations at various intervals associated with the processing, as long as the processing of the overlay operations are performed in a desired way.

Although the foregoing invention has been described in some detail for the purposes of clarity, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. An inductor structure, comprising:
a first elongated segment that runs parallel to a longitudinal axis of the inductor structure; and
a second elongated segment that is coupled to the first elongated segment and that runs parallel to the longitudinal axis, wherein the first elongated segment conveys a current in a first direction, and wherein the second elongated segment conveys the current in a second direction that is different than the first direction.

2. The inductor structure as defined in claim 1, further comprising:
a third elongated segment that runs parallel to the longitudinal axis and that conveys the current in the first direction, wherein the first, second, and third elongated segments are coupled in series.

3. The inductor structure as defined in claim 1, wherein the inductor structure has a periphery, and wherein the first and second elongated segments are formed along the periphery of the inductor structure.

4. The inductor structure as defined in claim 1, wherein the inductor structure has a shape that is a selected from a group of shapes consisting of: a rectangular shape, a pentagonal shape, a hexagonal shape, and an octagonal shape.

5. The inductor structure as defined in claim 1, further comprising:
a first terminal that is coupled to the first elongated segment; and
a second terminal that is coupled to the second elongated segment.

6. The inductor structure as defined in claim 1, wherein the first and second elongated segments are separated by less than 15 microns.

7. The inductor structure as defined in claim 1, wherein the inductor structure is formed in a dielectric stack on a semiconductor substrate, wherein the first elongated segment is formed in a first metal routing layer in the dielectric stack, and wherein the second elongated segment is formed in a second metal routing layer that is different than the first metal routing layer in the dielectric stack.

8. The inductor structure as defined in claim 1, wherein the inductor structure is formed in a dielectric stack on a semiconductor substrate, and wherein the first and second elongated segments are formed in a common metal routing layer in the dielectric stack.

9. The inductor structure as defined in claim 1, further comprising:
a third segment that has a first end coupled to the first elongated segment and a second end coupled to the second elongated segment, wherein the current is conveyed from the first elongated segment to the second elongated segment through the third segment.

10. The inductor structure as defined in claim 9, wherein the third segment is substantially shorter than the first and second elongated segments.

11. The inductor structure as defined in claim 1, wherein the first and second elongated segments are formed over a substrate having a resistivity of less than 10 Ohms per centimeter.

12. An integrated circuit, comprising:
a substrate;
an interconnect stack formed on the substrate; and
an inductor formed in the interconnect stack, wherein the inductor comprises:
a first elongated member that conveys a current in a first direction; and
a second elongated member that conveys the current in a second direction that is opposite from the first direction.

13. The integrated circuit as defined in claim 12, wherein the substrate has a resistivity of less than 10 Ohms per centimeter.

14. The integrated circuit as defined in claim 12, wherein the inductor has a quality factor value that is greater than 9.

15. The integrated circuit as defined in claim 12, wherein the inductor has a shape that is a selected from a group of shapes that consist of: a rectangular shape, a U-shape, a multi-turn U-shape, and a dual-U shape.

16. The integrated circuit as defined in claim 12, wherein the inductor forms a part of a circuit that is selected from a group of circuit that consist of: an inductor capacitor (LC) tank circuit, a voltage controller oscillator (VCO) circuit, a filter circuit, an amplifier circuit, and a frequency divider circuit.

17. The integrated circuit as defined in claim 12, further comprising:
a metal shielding layer formed in an interconnect stack layer adjacent to the first and second elongated segments, wherein the metal shielding reduces crosstalk signals between the first and second elongated segments.

18. A method of manufacturing an integrated circuit having a substrate and a dielectric stack on the substrate, the method comprising:
forming a first elongated segment in the dielectric stack; and
forming a second elongated segment in the dielectric stack, wherein the first and second elongated segments form part of an inductor, and wherein the first and second elongated segments convey currents in opposing directions.

19. The method as defined in claim 18, further comprising:
forming a third segment in the dielectric stack, wherein the third segment has a first end that is coupled to the first elongated segment and a second end that is coupled to the second elongated segment.

20. The method as defined in claim 19, further comprising:
forming a fourth segment in the dielectric stack, wherein the fourth segment has an end that is coupled to the first elongated segment and runs parallel to the third segment.

21. The method as defined in claim 20, further comprising:
forming the inductor to have a shape that is a selected from a group of shapes consisting of: a rectangular shape, a multi-turn U-shape, and a dual-U shape, wherein the first and second elongated segments and the third and fourth segment forms part of the inductor.
